(19) United States
(12) Patent Application Publication
(10) Pub. No.: US 2026/0082485 A1
(43) Pub. Date: Mar. 19, 2026

(54) SEMICONDUCTOR MODULE AND INSERT MOLDING METHOD

(71) Applicant: FUJI ELECTRIC CO., LTD., Kawasaki-shi (JP)

(72) Inventor: Hisato INOKUCHI, Matsumoto-city (JP)

(73) Assignee: FUJI ELECTRIC CO., LTD., Kawasaki-shi (JP)

(21) Appl. No.: 19/280,871

(22) Filed: Jul. 25, 2025

(30) Foreign Application Priority Data
Sep. 17, 2024 (JP) 2024-160463

(51) Int. Cl. H05K 1/18; H01L 23/00; H05K 3/34

(52) U.S. Cl. CPC H05K 1/181; H05K 3/3405; H05K 2201/10166; H05K 2201/10553; H05K 2201/10787; H05K 2201/10977; H05K 2203/1316; H10W 90/734

(57) ABSTRACT

A semiconductor module includes an insulated circuit board having an insulating member, a conductive plate arranged on the insulating member, and a semiconductor chip mounted on the conductive plate, and an insert-molded external connection terminal that includes a plurality of terminals, respectively connected to the insulated circuit board, and including a first terminal, and a pre-molded resin member that includes a pre-molded terminal fitting portion and a pre-molded pin insertion portion. The terminal fitting portion is made of a first resin material and has a first groove into which the first terminal is fitted. The pin insertion portion is made of the first resin material and has a hole configured to receive a pin arranged in a cavity of a metal mold used for insert-molding of the external connection terminal.

### CROSS-REFERENCE TO RELATED APPLICATION

This application is based upon and claims the benefit of priority of the prior Japanese Patent Application No. 2024-160463, filed on Sep. 17, 2024, the entire contents of which are incorporated herein by reference.

### BACKGROUND OF THE INVENTION

### 1. Field of the Invention

The embodiment discussed herein relates to a semiconductor module and an insert molding method.

### 2. Background of the Related Art

In insert molding, a bus bar includes terminal portions connected to a power conversion part, a conductive portion connecting the terminal portions, and an inclined portion in which the conductive portion is inclined with respect to an attachment surface of an enclosure (see, for example, Japanese Laid-open Patent Publication No. 2020-022239). In addition, a part of resin is disposed in a cavity together with an insert part before molding, and the resin is molded by partially accelerating or delaying the hardening of the resin in the cavity (see, for example, Japanese Laid-open Patent Publication No. 2004-174839). Further, after a plurality of insert parts are integrated by primary resin in a primary molding step, the plurality of insert parts integrated by the primary resin are integrated by secondary resin in a secondary molding step to manufacture an insert-molded product (Japanese Laid-open Patent Publication No. 2001-293744).

### SUMMARY OF THE INVENTION

According to an aspect of the present disclosure, there is provided a semiconductor module, including: an insulated circuit board having an insulating member, a conductive plate arranged on the insulating member, and a semiconductor chip mounted on the conductive plate; and an insert-molded external connection terminal that includes a plurality of terminals, respectively connected to the insulated circuit board, the plurality of terminals that includes a first terminal, and a pre-molded resin member that includes a pre-molded terminal fitting portion and a pre-molded pin insertion portion, the terminal fitting portion made of a first resin material and having a first groove into which the first terminal is fitted, the pin insertion portion made of the first resin material and having a hole configured to receive a pin arranged in a cavity of a metal mold used for insert-molding of the external connection terminal.

The object and advantages of the invention will be realized and attained by means of the elements and combinations particularly pointed out in the claims. p It is to be understood that both the foregoing general description and the following detailed description are exemplary and explanatory and are not restrictive of the invention.

### BRIEF DESCRIPTION OF THE DRAWINGS

FIG. 1 illustrates an example of a terminal portion to be insert-molded;

FIG. 2 illustrates an example of a molding resin part;

FIG. 3 illustrates the example of a molding resin part;

FIG. 4 illustrates an example of a state in which terminals are fixed by a molding resin part;

FIG. 5 is a flowchart illustrative of an example of a semiconductor module manufacturing method including a terminal insert molding method;

FIG. 6 illustrates an example of an insert-molded product;

FIG. 7 illustrates an example of a terminal to be insert-molded;

FIG. 8 illustrates an example of an insert finished product taken as a reference example;

FIGS. 9A to 9F illustrate an example of the structure of a semiconductor module; and

FIG. 10 is a view for describing an example of a positioning operation by a molding resin part having an inclined portion.

### DETAILED DESCRIPTION OF THE INVENTION

An embodiment will now be described with reference to the accompanying drawings. Components in the specification and drawings which have substantially the same functions are marked with the same numerals. By doing so, duplicate description may be omitted. Furthermore, in the following description, the term “upper” or “upward” indicates an upward direction from the surface of paper. Similarly, the term “lower” or “downward” indicates a downward direction from the surface of paper. These terms mean these directions in all the drawings. The terms “upper”, “upward”, “lower”, and “downward” are simply used as expedient representation for specifying relative positional relationships and do not limit the technical idea of the present disclosure.

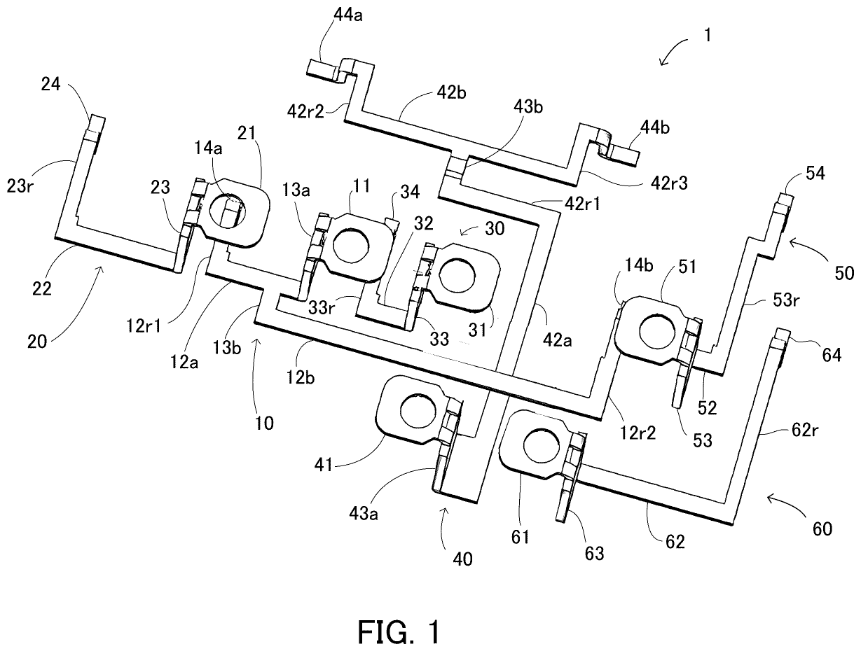

A molding resin part and insert molding according to an embodiment will be described with reference to FIGS. 1 to 6. FIG. 1 illustrates an example of a terminal portion to be insert-molded. An external connection terminal 1 includes terminals (lead terminals) 10, 20, 30, 40, 50, and 60. The terminals 10, 20, 30, 40, 50, and 60 are made of metal having good electrical conductivity. Such a metal is, for example, copper, aluminum, or an alloy containing at least one of them as a main component. Furthermore, the surfaces of the terminals 10, 20, 30, 40, 50, and 60 may be plated. At this time, a plating material used is, for example, nickel, a nickel-phosphorus alloy, or a nickel-boron alloy.

The terminal 10 forms an external terminal 11 connected to an external device. The terminal 10 includes a horizontal portion 12a, and the horizontal portion 12a is connected by a connection portion 13a extending in a vertical direction from the external terminal 11. A bent portion 12r1 perpendicular to the horizontal portion 12a is formed at an end portion of the horizontal portion 12a. A connection terminal 14a extending downward is formed at an end portion of the bent portion 12r1.

Furthermore, the terminal 10 includes a horizontal portion 12b. The horizontal portion 12b extends in a direction parallel to the horizontal portion 12a and away from the formation position of the connection terminal 14a of the horizontal portion 12a, and is connected to the horizontal portion 12a by a connection portion 13b. A bent portion 12r2 perpendicular to the horizontal portion 12b is formed at an end portion of the horizontal portion 12b. A connection terminal 14b extending downward is formed at an end portion of the bent portion 12r2.

The terminal 20 forms an external terminal 21 connected to an external device. The terminal 20 includes a horizontal portion 22, and the horizontal portion 22 is connected by a connection portion 23 extending in the vertical direction from the external terminal 21. A bent portion 23r perpendicular to the horizontal portion 22 is formed at an end portion of the horizontal portion 22. A connection terminal 24 extending downward is formed at an end portion of the bent portion 23r.

The terminal 30 forms an external terminal 31 connected to an external device. The terminal 30 includes a horizontal portion 32, and the horizontal portion 32 is connected by a connection portion 33 extending in the vertical direction from the external terminal 31. A bent portion 33r perpendicular to the horizontal portion 32 is formed at an end portion of the horizontal portion 32. A connection terminal 34 extending downward is formed at an end portion of the bent portion 33r.

The terminal 40 forms an external terminal 41 connected to an external device. The terminal 40 includes a horizontal portion 42a, and the horizontal portion 42a is connected by a connection portion 43a extending in the vertical direction from the external terminal 41. A bent portion 42r1 perpendicular to the horizontal portion 42a is formed at an end portion of the horizontal portion 42a in an extending direction.

Furthermore, the terminal 40 includes a horizontal portion 42b, and the horizontal portion 42b is connected by a connection portion 43b extending in the vertical direction from an end portion of the bent portion 42r1. A bent portion 42r2 perpendicular to the horizontal portion 42b is formed at one end portion of the horizontal portion 42b. A connection terminal 44a extending downward is formed at an end portion of the bent portion 42r2. In addition, a bent portion 42r3 perpendicular to the horizontal portion 42b is formed at the other end portion of the horizontal portion 42b. A connection terminal 44b extending downward is formed at an end portion of the bent portion 42r3.

The terminal 50 forms an external terminal 51 connected to an external device. The terminal 50 includes a horizontal portion 52, and the horizontal portion 52 is connected by a connection portion 53 extending in the vertical direction from the external terminal 51. A bent portion 53r perpendicular to the horizontal portion 52 is formed at an end portion of the horizontal portion 52. A connection terminal 54 extending downward is formed at an end portion of the bent portion 53r.

The terminal 60 forms an external terminal 61 connected to an external device. The terminal 60 includes a horizontal portion 62, and the horizontal portion 62 is connected by a connection portion 63 extending in the vertical direction from the external terminal 61. A bent portion 62r perpendicular to the horizontal portion 62 is formed at an end portion of the horizontal portion 62. A connection terminal 64 extending downward is formed at an end portion of the bent portion 62r.

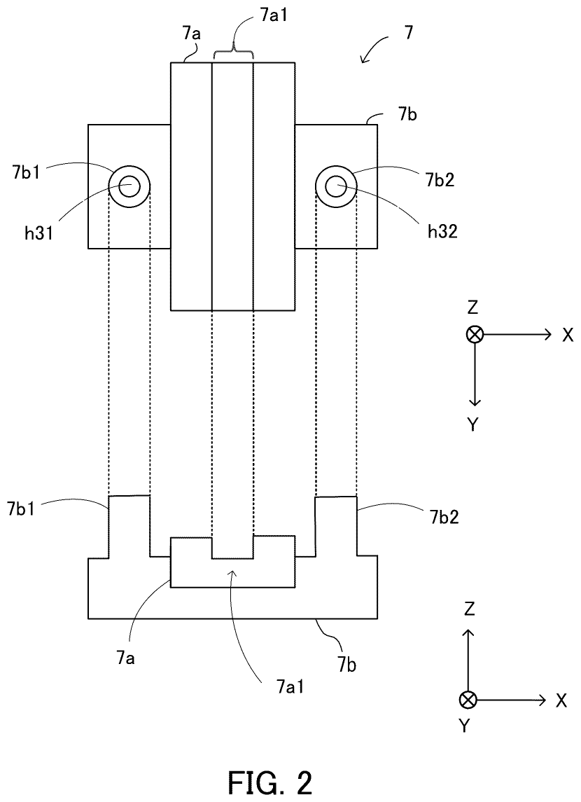

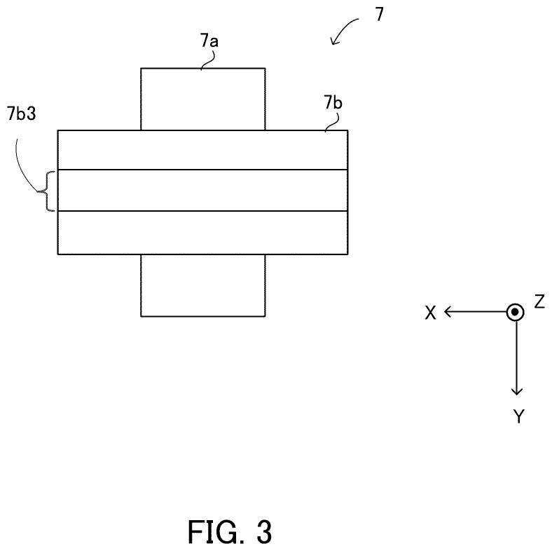

FIGS. 2 and 3 illustrate an example of a molding resin part. FIG. 2 illustrates a front surface and a side surface of a molding resin part 7. FIG. 3 illustrates a back surface of the molding resin part 7. The molding resin part (primary molding resin part) 7 has a terminal fitting portion 7a and a pin insertion portion 7b. The terminal fitting portion 7a and the pin insertion portion 7b are integrally formed. A groove 7a1 is cut in the terminal fitting portion 7a as a terminal positioning mechanism for fitting and fixing a part of a terminal 10, 20, 30, 40, 50, or 60 at the time of insert molding of the external connection terminal 1. The terminal fitting portion 7a is molded with a first resin by primary molding.

Protrusions 7b1 and 7b2 into which pins (guide pins) arranged in a cavity of a metal mold used for secondary molding are inserted at the time of insert molding of the external connection terminal 1 are formed on the front surface of the pin insertion portion 7b. The protrusions 7b1 and 7b2 have holes h31 and h32 at the ends thereof, respectively. The positions or the number of the protrusions 7b1 and 7b2 are arbitrarily selected according to the positions or the number of pins on the metal mold side. Furthermore, as illustrated in FIG. 3, a groove 7b3 is cut in the back surface of the pin insertion portion 7b as a terminal positioning mechanism for fitting and fixing a part of a terminal 10, 20, 30, 40, 50, or 60 at the time of insert molding of the external connection terminal 1. In the example of FIG. 3, the groove 7b3 is cut in a direction perpendicular to the groove 7a1.

The molding resin part 7 having the terminal fitting portion 7a and the pin insertion portion 7b is molded with the first resin by the primary molding. The first resin is, for example, a thermoplastic resin. For example, such a resin is polyphenylene sulfide resin, polybutylene terephthalate resin, polybutylene succinate resin, polyamide resin, or acrylonitrile butadiene styrene resin.

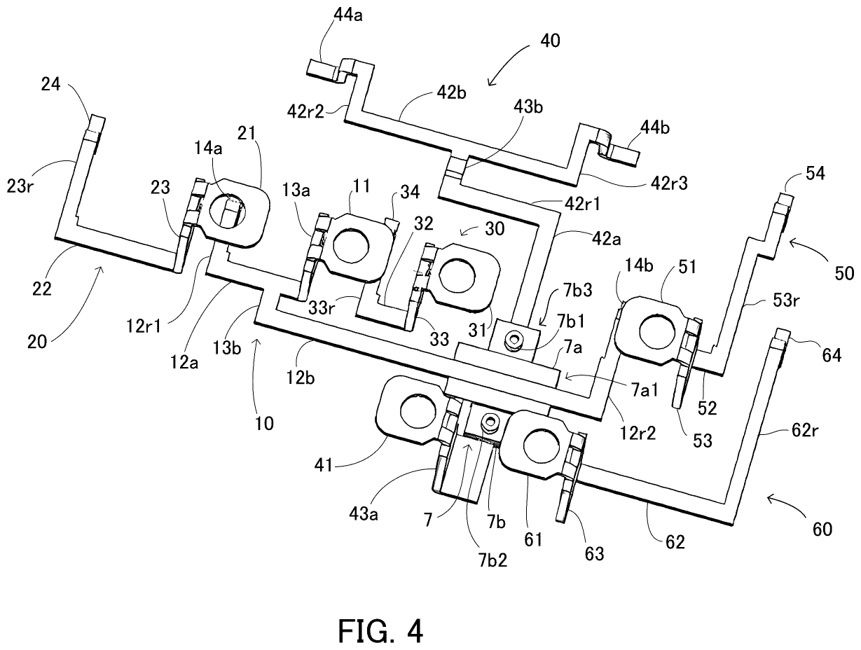

FIG. 4 illustrates an example of a state in which terminals are fixed by the molding resin part. When the external connection terminal 1 in which the terminals 10, 20, 30, 40, 50, and 60 are combined is molded, the horizontal portion 12b of the terminal 10 (first terminal) is fitted into the groove 7a1 (first groove) cut in the terminal fitting portion 7a of the molding resin part 7. Furthermore, the horizontal portion 42a of the terminal 40 (second terminal) is fitted into the groove 7b3 (second groove) cut in the pin insertion portion 7b of the molding resin part 7.

Although FIG. 4 illustrates a state in which the horizontal portion 12b of the terminal 10 is fitted into the groove 7a1 and in which the horizontal portion 42a of the terminal 40 is fitted into the groove 7b3, any portions of the other terminals may be fitted into the grooves 7a1 and 7b3 according to a work method of insert molding.

As described above, the horizontal portion 12b of the terminal 10 is fitted into the groove 7a1 of the molding resin part 7 and the horizontal portion 42a of the terminal 40 is fitted into the groove 7b3 of the molding resin part 7. By doing so, the terminal 10 and the terminal 40 are fixed with a stipulated insulation distance therebetween via the molding resin part 7. Therefore, the terminal 10 and the terminal 40 are positioned and fixed while ensuring insulation therebetween.

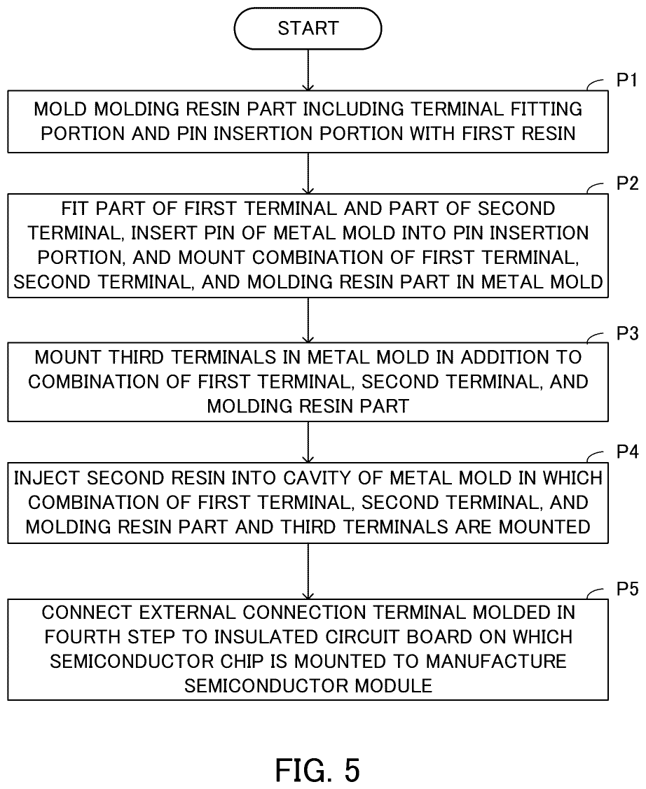

FIG. 5 is a flowchart illustrative of an example of a semiconductor module manufacturing method including a terminal insert molding method.

[First Step P1] The molding resin part 7 including the terminal fitting portion 7a having the groove 7a1 into which a part of the first terminal is fitted and the pin insertion portion 7b having the groove 7b3 into which a part of the second terminal is fitted and the holes h31 and h32 into which the pins arranged in the cavity of the metal mold used for the secondary molding are inserted is molded with the first resin by the primary molding. The part of the first terminal fitted into the groove 7a1 corresponds to the horizontal portion 12b of the terminal 10 and the part of the second terminal fitted into the groove 7b3 corresponds to the horizontal portion 42a of the terminal 40.

[Second Step P2] The horizontal portion 12b of the terminal 10 is fitted into the groove 7a1 of the terminal fitting portion 7a, the horizontal portion 42a of the terminal 40 is fitted into the groove 7b3 of the pin insertion portion 7b, and the pins arranged in the cavity of the metal mold are inserted into the holes h31 and h32 of the pin insertion portion 7b. By doing so, a combination of the first terminal (terminal 10), the second terminal (terminal 40), and the molding resin part 7 is mounted in the metal mold.

[Third Step P3] In addition to the combination of the first terminal (terminal 10), the second terminal (terminal 40), and the molding resin part 7, third terminals other than the first terminal and the second terminal are mounted in the metal mold. The third terminals correspond to the terminal 20, 30, 50, and 60.

[Fourth Step P4] By injection molding of secondary molding, a second resin is injected into the cavity of the metal mold in which the combination of the first terminal (terminal 10), the second terminal (terminal 40), and the molding resin part 7 and the third terminal (terminal 20, 30, 50, or 60) are mounted. By doing so, the combination of the first terminal (terminal 10), the second terminal (terminal 40), and the molding resin part 7 and the third terminals (terminal 20, 30, 50, and 60) are integrally molded, thereby molding the external connection terminal.

[Fifth Step P5] A semiconductor module is manufactured by connecting the external connection terminal to an insulated circuit board arranged on an insulating member and having a conductive plate on which a semiconductor chip is mounted.

The second resin used in the secondary molding and the first resin used at the time of molding the molding resin part 7 may be made of the same material. Alternatively, the first resin may have a higher insulating property than the second resin used at injection molding time in the secondary molding.

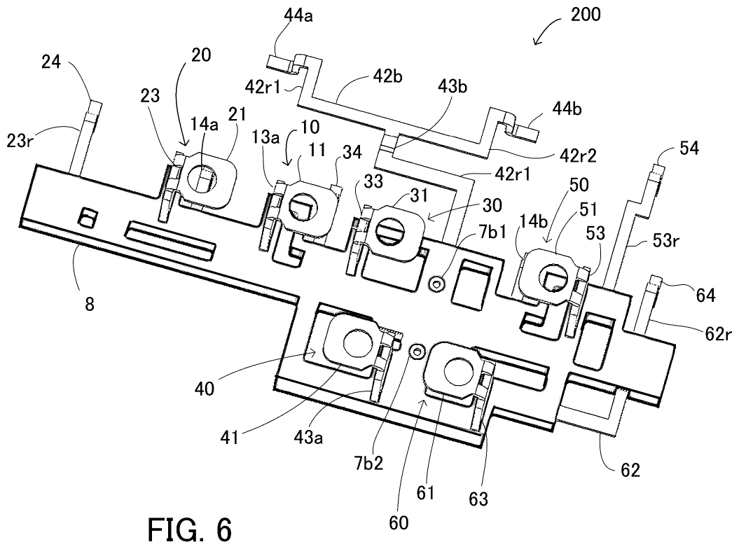

FIG. 6 illustrates an example of an insert-molded product. In the insert-molded product 200, insert molding (secondary molding) is performed by setting in a metal mold a state in which a part of the external connection terminal 1 obtained by combining the terminals 10, 20, 30, 40, 50, and 60 is fixed by the terminal fitting portion 7a of the molding resin part 7 illustrated in FIG. 3.

In this case, the terminals 10 and 40 are fixed in appropriate positions by the groove 7a1 of the terminal fitting portion 7a and the groove 7b3 of the pin insertion portion 7b, respectively, of the molding resin part 7, the terminal 40 is fixed in an appropriate position by the groove 7b3 of the pin insertion portion 7b of the molding resin part 7, and the pins arranged in the metal mold are inserted into the holes h31 and h32 of the protrusions 7b1 and 7b2 formed on the pin insertion portion 7b of the molding resin part 7. As a result, the terminals 10 and 40 are supported. In this state, a resin (secondary resin member) 8 melted by heat is injected into the metal mold and is cooled. After that, the metal mold is opened to take out the insert-molded product 200 in which the external connection terminal 1 and the resin 8 are integrated.

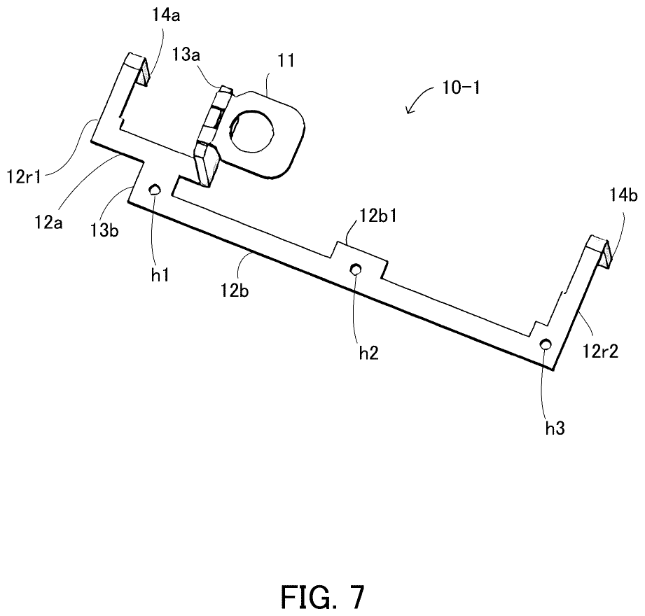

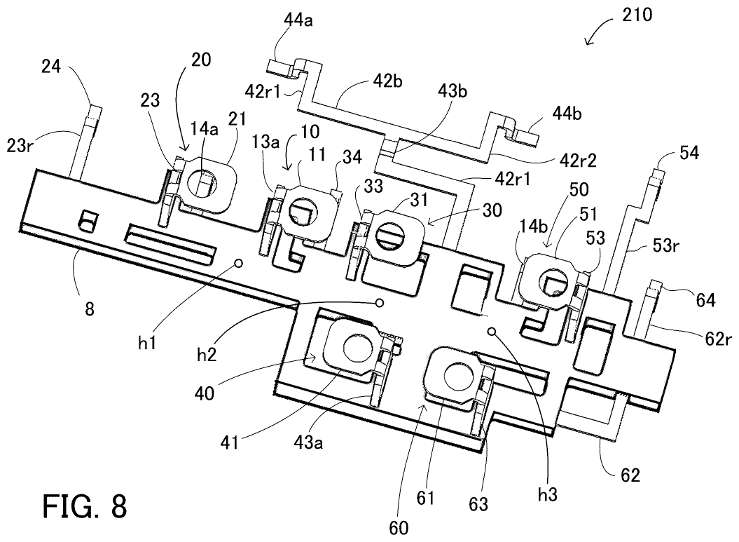

Next, insert molding taken as a reference example will be described with reference to FIGS. 7 and 8. FIG. 7 illustrates an example of a terminal to be insert-molded. A terminal 10-1 forms an external terminal 11 connected to an external device. The terminal 10-1 includes a horizontal portion 12a and the horizontal portion 12a is connected by a connection portion 13a extending in the vertical direction from the external terminal 11. A bent portion 12r1 perpendicular to the horizontal portion 12a is formed at an end portion of the horizontal portion 12a. A connection terminal 14a extending downward is formed at an end portion of the bent portion 12r1.

Furthermore, the terminal 10-1 includes a horizontal portion 12b. The horizontal portion 12b extends in a direction parallel to the horizontal portion 12a and away from the formation position of the connection terminal 14a of the horizontal portion 12a. The horizontal portion 12b is connected to the horizontal portion 12a by a connection portion 13b. A bent portion 12r2 perpendicular to the horizontal portion 12b is formed at an end portion of the horizontal portion 12b. A connection terminal 14b extending downward is formed at an end portion of the bent portion 12r2.

In addition, with the terminal 10-1, a fixing hole h1 is made in the connection portion 13b and a fixing hole h2 is made in a protrusion 12b1 formed in the center of the horizontal portion 12b. Moreover, a fixing hole h3 is made in a connection portion of the horizontal portion 12b and the bent portion 12r2.

FIG. 8 illustrates an example of an insert finished product taken as a reference example. With an insert finished product 210, in addition to the terminal 10-1 illustrated in FIG. 7, a plurality of terminals (terminals 20, 30, 40, 50, and 60 illustrated in FIG. 1) having shapes different from the shape of the terminal 10-1 are combined and are fixed in this state by a resin 8. Insert molding is performed.

When such an insert finished product 210 is molded, pins arranged in a metal mold are inserted into the fixing holes h1, h2, and h3 made in the terminal 10-1 to support the terminal 10-1. The terminals 20, 30, 40, 50, and 60 are further combined, and the resin 8 melted by heat is injected into the metal mold and is cooled. After that, the metal mold is opened, and the insert finished product 210 in which the terminals 10-1, 20, 30, 40, 50, and 60 and the resin 8 are integrated is taken out.

With the insert molding taken as a reference example, the pins arranged in the metal mold are inserted into the fixing holes h1, h2, and h3 of the terminal 10-1 to support the outer shape portion. This prevents deformation of the terminal 10-1 due to the injection pressure of the resin 8 or deterioration in positional accuracy due to the movement of the terminal 10-1 inside the resin 8.

With the above insert molding taken as a reference example, the fixing holes h1, h2, and h3 are made in the terminal 10-1 and the terminal 10-1 is supported by the pins in the metal mold for the insert molding. By doing so, deformation or positional deviation of the terminal 10-1 due to the flow of the resin 8 is suppressed. However, the pins in the metal mold are inserted into portions (portions of the fixing holes h1, h2, and h3) supported by the metal mold. As a result, these portions are not filled with the resin 8. Therefore, with the insert finished product 210, the portions supported by the metal mold are not covered with the resin 8.

That is to say, there is a portion in which insulation performance is not ensured. Alternatively, in order to secure insulation distance, supported portions are limited. When fixing holes are made in limited portions in the terminal to support by pins in a metal mold, there is a possibility that deformation or positional deviation of the terminal due to the flow of the resin 8 is effectively suppressed.

Specifically, when insert molding is performed by combining the terminals 20, 30, 40, 50, and 60 with the terminal 10-1, it is difficult to secure insulation distance between the external terminals 11, 21, 31, 41, 51, and 61. Due to such difficulties, a restriction on a supported portion for securing insulation distance is tightened.

In order to suppress deformation or positional deviation of the terminals due to the flow of the resin 8, a method other than the above insert molding taken as a reference example is possible. That is to say, in the primary molding, the terminals are covered with resin or spaces between the terminals are filled with resin. By doing so, rigidity is ensured. The secondary molding is performed in this state. However, to secure positional accuracy by performing the primary molding and secure insulation by the secondary molding is inferior in costs and manufacturing period (delivery date).

On the other hand, with the present embodiment, the terminals are not directly fixed by the metal mold at the time of the secondary molding. The terminals are fixed via the molding resin part 7. Therefore, the insert-molded product 200 has a structure in which the terminals are covered with the resin 8. As a result, the support portion in the insert-molded product 200 is covered with the molding resin part 7. Accordingly, it is possible to secure insulation performance in the support portion. Furthermore, in the present embodiment, it is possible to reduce the labor of terminal insertion (setting terminals in a metal mold) at the time of the primary molding, compared with a method for insert-molding terminals twice, that is to say, insert-molding terminals by primary molding and secondary molding.

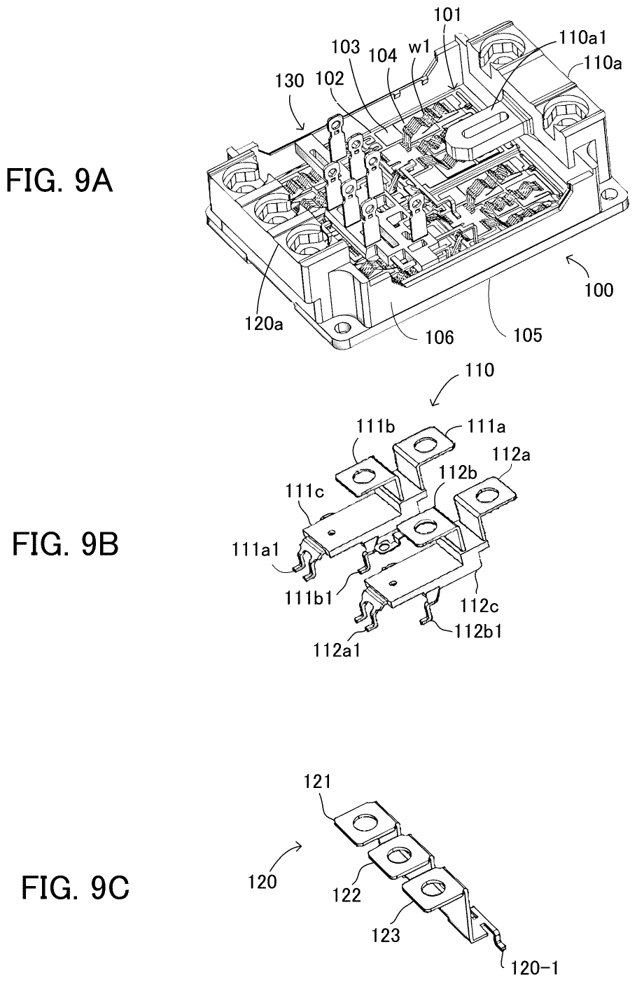

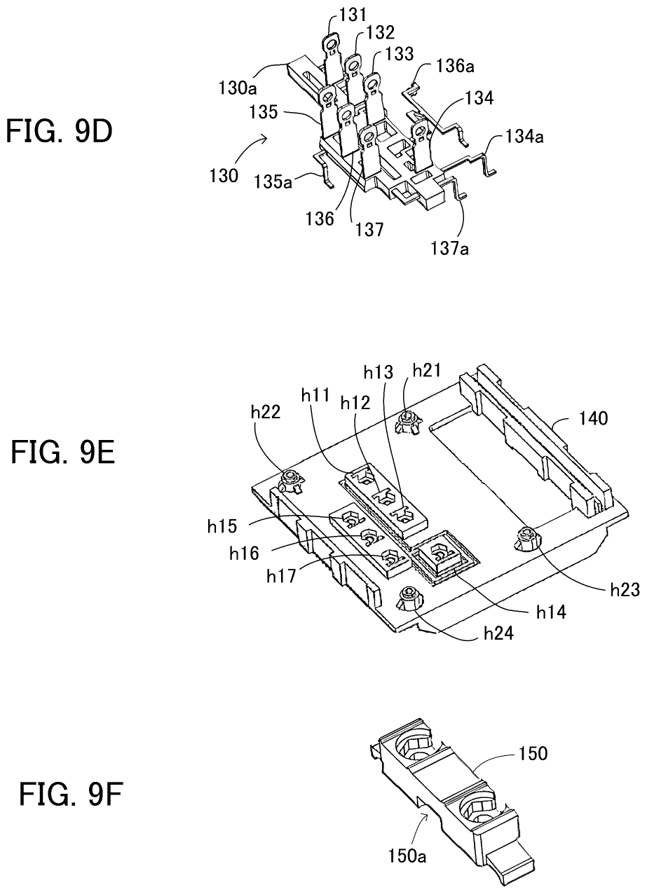

A semiconductor module having external connection terminals insert-molded by the use of the molding resin part according to the present embodiment will now be described with reference to FIGS. 9A to 9F. FIGS. 9A to 9F illustrate an example of the structure of a semiconductor module. A semiconductor module 100 includes an insulated circuit board 101. The insulated circuit board 101 includes an insulating member 102 and a plurality of conductive plates 103 formed on the front surface of the insulating member 102.

The insulating member 102 is made of a ceramic having high thermal conductivity. Such a ceramic is made of, for example, a material containing aluminum oxide, silicon nitride, or aluminum nitride as a main component.

Each conductive plate 103 is made of metal having good electrical conductivity. Such metal is, for example, copper, aluminum, or an alloy containing at least one of them. In order to improve the corrosion resistance of each conductive plate 103, plating treatment may be performed. At this time, a plating material used is, for example, nickel, a nickel-phosphorus alloy, or a nickel-boron alloy.

Furthermore, a semiconductor chip 104 is mounted on a conductive plate 103 with a bonding material. The semiconductor chip 104 may contain silicon carbide as a main component. Such a semiconductor chip is, for example, a power metal-oxide-semiconductor field-effect transistor (MOSFET). In this case, the semiconductor chip 104 includes on the lower surface a drain electrode as an input electrode and includes on the upper surface a gate electrode as a control electrode and a source electrode as an output electrode. In addition, the semiconductor chip 104 may contain silicon as a main component. Such a semiconductor chip may include a reverse conducting-insulated gate bipolar transistor (RC-IGBT) having the functions of both of an IGBT and a free wheeling diode (FWD). In this case, the semiconductor chip 104 includes on the lower surface a collector electrode as an input electrode and includes on the upper surface a gate electrode as a control electrode and an emitter electrode as an output electrode. An upper surface electrode of the semiconductor chip 104 and a predetermined conductive plate 103 are connected by a bonding wire w1.

Furthermore, the semiconductor module 100 includes a radiation plate (base) 105 arranged on the back surface of the insulated circuit board 101 and a case 106 arranged on the radiation plate 105 to cover side surfaces. The radiation plate 105 is a member having the shape of a plate which is approximately rectangular in plan view. Corner portions of the radiation plate 105 may be R-chamfered or C-chamfered. The radiation plate 105 is made of metal having an excellent heat dissipation property. Such metal is, for example, copper, aluminum, silicon carbide, or an alloy containing at least one of them. The surface of the radiation plate 105 may be plated to improve corrosion resistance. A plating material used at this time is, for example, nickel, a nickel-phosphorus alloy, or a nickel-boron alloy.

The case 106 is made of a thermoplastic resin. Such a resin is, for example, polyphenylene sulfide resin, polybutylene terephthalate resin, polybutylene succinate resin, polyamide resin, or acrylonitrile butadiene styrene resin.

A main terminal location portion 110a is formed at an end portion of the case 106 and a protrusion 110a1 is formed on a side surface of the main terminal location portion 110a on the housing side of the case 106. A recess 150a is formed in the center of a nut housing portion 150 and the nut housing portion 150 is placed by fitting the protrusion 110a1 into the recess 150a. A PN main terminal 110 is arranged on the main terminal location portion 110a and the nut housing portion 150. The PN main terminal 110 has a structure including a pair of a P main terminal 111a and an N main terminal 111b and a pair of a P main terminal 112a and an N main terminal 112b. The P main terminal 111a and the N main terminal 111b are fixed by a terminal holding portion 111c made of a resin material in order to maintain insulation. The P main terminal 112a and the N main terminal 112b are fixed by a terminal holding portion 112c made of a resin material in order to maintain insulation.

One end of the P main terminal 111a is exposed from the upper surface of the case 106 and a connection terminal 111a1 extending toward the insulated circuit board 101 is formed at the other end of the P main terminal 111a. Furthermore, one end of the N main terminal 111b is exposed from the upper surface of the case 106 and a connection terminal 111b1 extending toward the insulated circuit board 101 is formed at the other end of the N main terminal 111b.

One end of the P main terminal 112a is exposed from the upper surface of the case 106 and a connection terminal 112a1 extending toward the insulated circuit board 101 is formed at the other end of the P main terminal 112a. Furthermore, one end of the N main terminal 112b is exposed from the upper surface of the case 106 and a connection terminal 112b1 extending toward the insulated circuit board 101 is formed at the other end of the N main terminal 112b.

On the other hand, an output terminal location portion 120a is formed at an end portion of the case 106 opposite the main terminal location portion 110a and an output terminal 120 is arranged on the output terminal location portion 120a. The output terminal 120 includes a first output terminal 121, a second output terminal 122, and a third output terminal 123. One end of the output terminal 120 is exposed from the upper surface of the case 106 and a connection terminal 120-1 extending toward the insulated circuit board 101 is formed at the other end of the output terminal 120.

Moreover, an external connection terminal 130 is arranged on the conductive plate on the insulated circuit board 101. The external connection terminal 130 is formed by the insert molding according to the present embodiment and includes terminals 131, 132, 133, 134, 135, 136, and 137. The terminals 131, 132, 133, 134, 135, 136, and 137 are fixed by a terminal holding portion 130a made of a resin material in order to maintain insulation.

One end of each of the terminals 131, 132, 133, 134, 135, 136, and 137 is exposed from the upper surface of the case 106 and connection terminals extending toward the insulated circuit board 101 are formed at the other ends of the terminals 131, 132, 133, 134, 135, 136, and 137. For example, FIGS. 9A to 9F illustrate a connection terminal 134a formed at the other end of the terminal 134 and a connection terminal 135a formed at the other end of the terminal 135. Furthermore, a connection terminal 136a formed at the other end of the terminal 136 is illustrated and a connection terminal 137a formed at the other end of the terminal 137 is illustrated.

The conductive plate 103 and the semiconductor chip 104 on the insulated circuit board 101, the PN main terminal 110, the output terminal 120, and the external connection terminal 130 are bonded via solder. Alternatively, the PN main terminal 110, the output terminal 120, and the external connection terminal 130 may be bonded to predetermined conductive plates 103 on the insulated circuit board 101 by laser welding or ultrasonic welding. Lead-free solder is used as the solder. For example, the lead-free solder contains as a main component at least one of a tin-silver-copper alloy, a tin-zinc-bismuth alloy, a tin-copper alloy, and a tin-silver-indium-bismuth alloy. Instead of the solder, a sintered metal body may be used. A material for the sintered metal body is silver, gold, nickel, copper, or an alloy containing at least one of them.

On the other hand, a case 140 is fixed onto the upper surface of the semiconductor module 100. Terminal through holes h11, h12, h13, h14, h15, h16, and h17 are made in the case 140. When the case 140 is fixed onto the upper surface of the semiconductor module 100, the terminals 131, 132, 133, 134, 135, 136, and 137 are exposed through the terminal through holes h11, h12, h13, h14, h15, h16, and h17 respectively. Furthermore, screw holes h21, h22, h23, and h24 are made in the case 140 for attaching the case 140 to the semiconductor module 100 with screws.

The case 140 is molded by the use of a thermoplastic resin. The thermoplastic resin is, for example, polyphenylene sulfide resin, polybutylene terephthalate resin, polybutylene succinate resin, polyamide resin, or acrylonitrile butadiene styrene resin.

FIGS. 9A to 9F illustrate the structure of the semiconductor module 100 with the members separated. With the semiconductor module 100, the nut housing portion 150, the PN main terminal 110, the output terminal 120, and the external connection terminal 130 are incorporated into the case 106. The case 140 is put on the output terminal 120 and the external connection terminal 130. The periphery of the case 140 and the periphery of the case 106 are bonded to each other with an adhesive or the like. As a result, a finished product is manufactured.

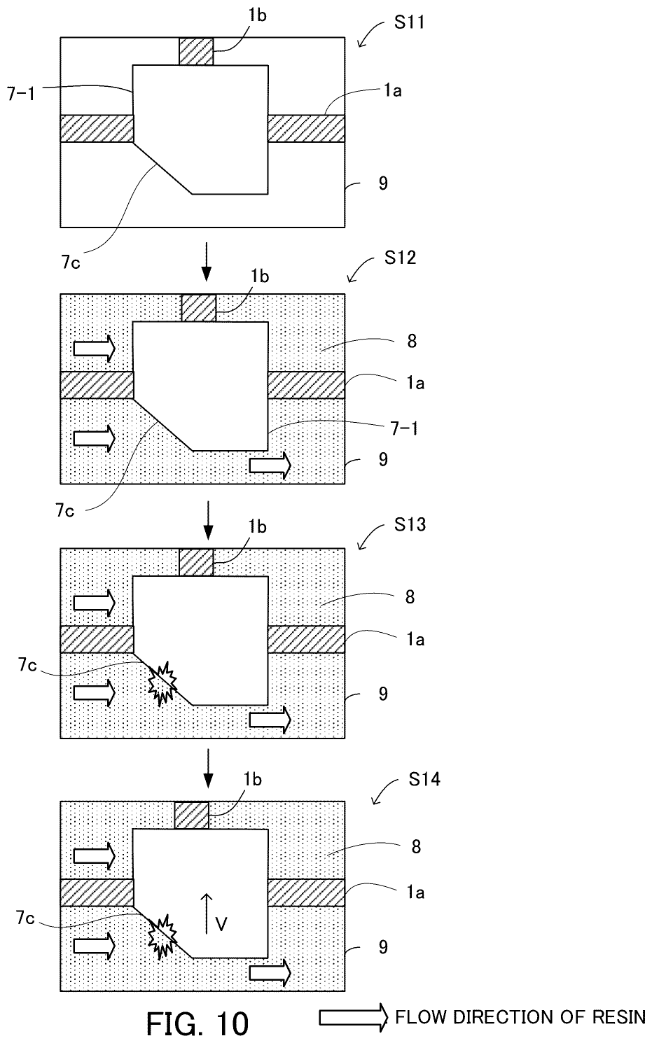

A molding resin part having an inclined shape will now be described with reference to FIG. 10. FIG. 10 is a view for describing an example of a positioning operation by a molding resin part having an inclined portion. A molding resin part 7-1 has an inclined portion 7c that receives the pressure of resin flowing at injection molding time. The inclined portion 7c is formed in the first step P1 illustrated in FIG. 5.

[Step S11] Terminals 1a and 1b are fixed by the molding resin part 7-1 having the inclined portion 7c and are set in a metal mold 9. The terminal 1a corresponds to, for example, the horizontal portion 12b of the terminal 10 and the terminal 1b corresponds to, for example, the horizontal portion 42a of the terminal 40.

[Step S12] At injection molding time, resin 8 flows out from a gate into a cavity of the metal mold 9.

[Step S13] The resin 8 flowing in the cavity hits the inclined portion 7c formed on the molding resin part 7-1.

[Step S14] Component force V is generated in the vertically upward direction with respect to the flow direction of the resin 8. The terminals 1a and 1b are pressed in the upward direction by the component force V generated in the vertically upward direction. As a result, positional accuracy is ensured.

As described above, the inclined portion 7c is formed on the molding resin part 7-1 and the pressure of the resin 8 flowing at injection molding time is received by the inclined portion 7c. By adopting this structure, the terminals 1a and 1b fixed by the molding resin part 7-1 are pressed in one direction. Therefore, positioning accuracy is improved.

In the above description, the molding resin part 7-1 has the inclined portion 7c. However, the molding resin part 7-1 may have a portion which differs from the inclined portion 7c in shape as long as it properly receives the pressure of the resin 8 flowing at injection molding time. For example, it is also possible to form a convex portion or a concave portion on the molding resin part 7-1 and improve positioning accuracy by a component force generated by receiving the pressure of the resin 8 flowing at injection molding time by the convex portion or the concave portion.

According to an aspect, in terminal insert molding, insulation distance is ensured and positioning accuracy is improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
an insulated circuit board having an insulating member, a conductive plate arranged on the insulating member, and a semiconductor chip mounted on the conductive plate; and
an insert-molded external connection terminal that includes
a plurality of terminals, respectively connected to the insulated circuit board, the plurality of terminals that includes a first terminal, and
a pre-molded resin member that includes a pre-molded terminal fitting portion and a pre-molded pin insertion portion, the terminal fitting portion made of a first resin material and having a first groove into which the first terminal is fitted, the pin insertion portion made of the first resin material and having a hole configured to receive a pin arranged in a cavity of a metal mold used for insert-molding of the external connection terminal.

2. The semiconductor module according to claim 1, wherein the pin insertion portion includes a protrusion having the hole at a tip thereof.

3. The semiconductor module according to claim 1, wherein
the plurality of terminals further includes a second terminal, and
the pin insertion portion further includes a second groove, and the second terminal is fitted into the second groove of the pre-molded resin member.

4. The semiconductor module according to claim 1, wherein
the plurality of terminals further includes a second terminal,
the pre-molded resin member has a shape configured to press the first terminal and the second terminal in a certain direction in the cavity of the metal mold by a component force of a pressure of a second resin material flowing during injection molding, and
the external connection terminal includes a secondary resin member made of the second resin material over the pre-molded resin member.

5. The semiconductor module according to claim 4, wherein the pre-molded resin member has an inclined shape configured to generate the component force in a vertically upward direction with respect to a direction in which the second resin material flows in the cavity of the metal mold.

6. The semiconductor module according to claim 1, wherein
the external connection terminal includes a secondary resin member, made of a second resin material, over the pre-molded resin member,
the first resin material and the second resin material are made of a same material.

7. The semiconductor module according to claim 1, wherein
the external connection terminal includes a secondary resin member, made of a second resin material, over the pre-molded resin member, and
the first resin material has an insulation property higher than an insulation property of the second resin material.

8. An insert molding method, comprising:
forming a pre-molded resin member by injecting a first resin material into a first metal mold, the pre-molded resin member including a terminal fitting portion having a first groove and a pin insertion portion having a hole;
mounting a combination of the first terminal, the second terminal, and the pre-molded resin member in a second metal mold by fitting the first terminal into the first groove of the terminal fitting portion and inserting a pin, arranged in a cavity of a second metal mold, into the hole of the pin insertion portion;
mounting a third terminal, different from the first terminal and the second terminal in the second metal mold; and
injecting a second resin material into the cavity of the second metal mold in which the combination of the first terminal, the second terminal, the pre-molding resin member and the third terminal are mounted to mold an external connection terminal by injection molding.

9. The insert molding method according to claim 8, further including
fitting the second terminal into a second groove formed in the pre-molded resin member.

10. The insert molding method according to claim 8, wherein the pin insertion portion includes a protrusion having the hole at a tip thereof.

11. The insert molding method according to claim 8, wherein the pre-molded resin member has a shape configured to press the first terminal and the second terminal in a certain direction by a component force of a pressure of the second resin material flowing in the cavity of the second metal mold during injection molding.

12. The insert molding method according to claim 11, wherein the pre-molded resin member has an inclined shape configured to generate the component force in a vertically upward direction with respect to a direction in which the second resin material flows in the cavity of the second metal mold.

13. The insert molding method according to claim 8, wherein the first resin material and the second resin material are made of a same material.

14. The insert molding method according to claim 8, wherein the first resin material has an insulating property higher than an insulating property of the second resin material.

15. A manufacturing method of a semiconductor module, comprising:
performing the insert molding method according to claim 8; and
after the external terminal is molded, connecting the external connection terminal to an insulated circuit board that includes
an insulating member, a conductive plate arranged on the insulating member, and a semiconductor chip mounted on the conductive plate.
